(19) United States
(12) Patent Application Publication
(10) Pub. No.: US 2010/0244878 A1
(43) Pub. Date: Sep. 30, 2010

(54) PLL BURN-IN CIRCUIT AND SEMICONDUCTOR INTEGRATED CIRCUIT

(76) Inventors: Yuji Yamada, Osaka (JP); Masayoshi Kinoshita, Osaka (JP); Kazuaki Sogawa, Osaka (JP); Junji Nakatsuka, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/521,192

(22) PCT Filed: Dec. 20, 2007
(86) PCT No.: PCT/JP2007/074486

§ 371 Date: Jun. 25, 2009

(30) Foreign Application Priority Data
Dec. 26, 2006 (JP) 2006-349313

(51) Int. Cl. G01R 31/02

(52) U.S. Cl. 324/763

(57) ABSTRACT

In a PLL which does not include a loop filter, an additional circuit for subjecting a voltage-controlled oscillator to a burn-in test with an appropriate oscillation frequency is realized by a less circuit configuration.

A gate terminal of a diode-connected transistor (13) which has the same polarity as a voltage-to-current conversion transistor (11) in a voltage-controlled oscillator (10) is connected to a gate terminal of the transistor (11) through a switch (12a), and a current supply (14) is connected to a drain terminal of the transistor (13). By appropriately controlling the current value supplied from the current supply (14) and the size ratio between the transistor (11) and the transistor (13), a current required for performing a burn-in test can be supplied to a ring oscillator in the voltage-controlled oscillator (10).

### TECHNICAL FIELD

The present invention relates to a circuit, which is used when performing a simple test on a voltage-controlled oscillator (VCO) in an analog PLL (Phase Locked Loop) which is embedded in a semiconductor integrated circuit and has a loop filter attached externally, and a semiconductor integrated circuit including an oscillation circuit. More specifically, the invention relates to a circuit which is used when performing a burn-in test on a voltage-controlled oscillator which does not flow a lower-limit current regardless of its control input voltage, i.e., which does not perform self-propelled oscillation.

### BACKGROUND ART

As shown in FIG. 16, a PLL for generating such as a system clock comprises a phase comparator (PFD) 8-1, a charge pump (CP) 8-2, a loop filter (FIL) 8-3, a voltage-controlled oscillator (VCO) 8-4, and a feedback frequency-divider (DIV) 8-5, and the PLL is operated as a frequency multiplier for generating a desired frequency by synchronizing the phase of a reference clock signal with the phase of an output signal from the feedback frequency-divider.

The operation of this PLL is as follows. That is, an externally supplied reference clock signal RCL is phase-compared with the output signal from the feedback frequency-divider 8-5 by the phase comparator 8-1, and a signal according to the phase comparison result is outputted to the charge pump 8-2. The high-frequency component of the signal according to the phase comparison result is cut by the loop-filter 8-3, and the resultant signal is outputted as a control voltage to the voltage-controlled oscillator 8-4. When the control voltage is applied, the voltage-controlled oscillator 8-4 oscillates a signal of a frequency according to the magnitude of the control voltage, and outputs this signal to the outside as a multiplied output signal OUT and also to the feedback frequency-divider 8-5. The feedback frequency-divider 8-5 frequency-divides the multiplied output signal OUT supplied from the voltage-controlled oscillator 8-4, and outputs its output signal toward the phase comparator 8-1.

The voltage-controlled oscillator 8-4 used in the PLL comprises, as shown in FIG. 17, a voltage-to-current conversion transistor 9-1 which converts the output voltage VC of the loop filter 8-3 into a current, a current mirror circuit 9-2 which copies the current that is obtained from the voltage by the voltage-to-current conversion transistor 9-1, and a ring oscillator 9-3 which is composed of odd-numbered stages of inverters connected in a ring shape, and is oscillated at a frequency that is approximately proportional to the current outputted from the current mirror circuit 9-2. The voltage-controlled oscillator 8-4 outputs a signal of a frequency according to the output voltage VD of the loop filter 8-3.

That is, the control voltage VC applied to the gate of the voltage-to-current conversion transistor 9-1 is converted into a current according to the magnitude of the voltage by the voltage-to-current conversion transistor 9-1. This current is converted by the current mirror circuit 9-2 into a current of a value according to the ratio of the sizes of transistors 9-2a and 9-2b which constitute the current mirror circuit 9-2. That is, by previously determining the sizes of the transistors 9-2a and 9-2b when fabricating these transistors, a current proportional to the current which is taken by the voltage-to-current conversion transistor 9-1 is outputted to the ring oscillator 9-3 as a control signal.

This control signal is supplied to an odd number of inverters constituting the ring oscillator 9-3, for example, three inverters 9-3a, 9-3b, and 9-3c shown in FIG. 17. Since the operation speed of each inverter is increased with an increase in the current value applied as its control signal, the oscillation frequency is varied according to the value of the control signal.

That is, when the voltage-to-current conversion transistor 9-1 is a NMOS transistor, as shown in FIG. 18, the output signal frequency of the voltage-controlled oscillator is 0 Hz when the output voltage of the loop filter is within a range from 0V to the voltage shown by 10-1, and when the output voltage of the loop filter exceeds the threshold voltage shown by 10-1, the frequency is increased in response to the exceeding voltage.

Accordingly, in order to oscillate the voltage-controlled oscillator by controlling the loop filter voltage, it is always necessary to supply a sufficient current to the ring oscillator in the voltage-controlled oscillator by applying a voltage higher than the threshold voltage 10-1 shown in FIG. 18. However, when such high voltage is excessively applied, too much current is supplied to the ring oscillator, and thereby the oscillation frequency is excessively increased. Further, since the voltage-to-current conversion transistor is likely to be affected by manufacturing variations, it is difficult to minutely control the oscillation frequency of the voltage-controlled oscillator by adjusting the voltage of the loop filter.

Although there are some voltage-controlled oscillators configured such that the lower-limit current is supplied to the ring oscillator so that it can be oscillated even when the loop filter voltage is lower than the threshold voltage 10-1, since supply of the lower-limit current might deteriorate the jitter performance of the output signal of the voltage-controlled oscillator, a voltage-controlled oscillator which does not supply the lower-limit current to the ring oscillator is used in the PLL which is desired to have the jitter performance.

By the way, there are cases where semiconductor integrated circuits are subjected to burn-in test before shipped to the market. The burn-in test is performed for the purpose of eliminating initial defectives, i.e., defective semiconductor integrated circuits immediately after starting to use at which the incidence rate of defectives is relatively high, and the burn-in test selects and eliminates initially defective individuals by placing burdens on the semiconductor integrated circuits before shipping.

Although the burn-in test is desired to be performed in the wafer level before assembly for cost reduction, it is not possible to perform the test with the external parts attached to the semiconductor integrated circuits in the wafer level. Accordingly, when the loop filter of the PLL is constituted by external parts, it is not possible to perform the burn-in test in the state where the PLL circuit and the loop filter are connected.

So, the burn-in test for PLL has conventionally been performed by the following methods. That is, as shown in FIG. 19, one of divided voltages generated by a voltage-division resistor 30 comprising resistors R1 to R4 is selected by a selector 40 to be applied to an input terminal of a voltage-controlled oscillator 8-4, thereby to oscillate the voltage-controlled oscillator 8-4 (for example, refer to Patent Document 1). Alternatively, as shown in FIG. 20, a selector 50 comprising two switches 50a and 50b is provided in a VCO 8-4, and an externally input pulse OP is selected instead of the original output signal from the VCO 8-4 according to a control input SCI to this selector 50, and this pulse OP is outputted as it is from the VCO 8-4 (for example, Patent Document 2).

Patent Document 1: Japanese Published Patent Application No. Hei. 9-5398 (FIG. 1)

Patent Document 2: Japanese Published Patent Application No. Hei. 10-65525 (FIG. 2)

### DISCLOSURE OF THE INVENTION

### Problems to be Solved by the Invention

By the way, the PLL whose loop filter is constituted by external parts while it is embedded in the semiconductor integrated circuit has several problems when it is subjected to the burn-in test by the method described in Patent Document 1.

First of all, when the divided voltage generated by the voltage-division resistor is applied to the voltage-controlled oscillator, the divided voltage might be a voltage of a value at which the voltage-controlled oscillator is not oscillated due to variations in the resistor elements, or it might be a voltage of a value at which the oscillation frequency of the voltage-controlled oscillator becomes too high. Further, while the plural resistor elements are used for generating the voltage to be applied to the voltage-controlled oscillator, the resistor elements formed in the semiconductor integrated circuit occupy a large area in the integrated circuit, resulting in an increase in cost.

Next, in the case of applying the pulse from the outside of the semiconductor integrated circuit by the method described in Patent Document 2, although the effect of the burn-in test can be expected for the blocks in the stages subsequent to the voltage-controlled oscillator because the signal is propagated to these blocks, the effect of the burn-in test cannot be expected for the voltage-controlled oscillator because the oscillator itself is not oscillated.

The present invention is made to solve the above-described problems and has for its object to provide a PLL burn-in circuit which can perform a burn-in test with an optimum frequency to a PLL which is embedded in a semiconductor integrated circuit and has a loop filter configured by external parts, and the semiconductor integrated circuit.

### Measures to Solve the Problems

In order to solve the above-described problems, according to claim 1 of the present invention, there is provided a PLL burn-in circuit which applies a burn-in voltage to a voltage-to-current conversion transistor for converting a voltage applied to its gate terminal into a current, the transistor being included in a voltage-controlled oscillator which constitutes a phase locked loop circuit (hereinafter referred to as a PLL) embedded in a semiconductor integrated circuit, and the PLL burn-in circuit comprising: a current supply having one end connected to a first power supply; a first transistor which has the same polarity as the voltage-to-current conversion transistor, and has a drain terminal connected to the other end of the current supply and a source terminal connected to a second power supply; and a voltage switching means which makes the voltage at the gate terminal of the voltage-controlled oscillator equal to the voltages at the gate terminal and the drain (or source) terminal of the first transistor when performing PLL burn-in, and makes the gate terminal of the voltage-to-current conversion transistor have a high impedance when performing normal operation; wherein, when performing a burn-in test, the first transistor is diode-connected to connect the gate terminal of the voltage-to-current conversion transistor with the gate terminal of the first transistor, and thereby the current that flows in the ring oscillator in the voltage-controlled oscillator can be determined according to the current that is supplied from the current supply and the size ratio between the voltage-to-current conversion transistor and the first transistor.

Therefore, the burn-in test can be performed with the appropriate frequency without practically being affected by variations in the voltage applied to the voltage-controlled oscillator and variations of the voltage-to-current conversion transistor in the voltage-controlled oscillator. Further, since the gate terminal of the voltage-to-current conversion transistor is in the high impedance state during the normal operation, the voltage-controlled oscillator can be operated without being affected by the attached PLL burn-in circuit.

Further, in order to solve the above-described problems, according to claim 2 of the present invention, in the PLL burn-in circuit disclosed in claim 1, the voltage switching means includes a diode connection path diode-connecting the gate terminal and the drain terminal of the first transistor, and a switching element which switches the state between the gate terminal of the voltage-to-current conversion transistor and the gate terminal of the first transistor, between the high-impedance state and the connected state.

Therefore, the state between the gate terminal of the voltage-to-current conversion transistor and the gate terminal of the first transistor is put in the high impedance state by using the switching circuit during the normal operation to put the control input terminal in the high impedance state, thereby to disconnect the PLL burn-in circuit from the voltage-controlled oscillator, while the gate terminal of the voltage-to-current conversion transistor is connected to the gate terminal of the first transistor during the burn-in test, thereby to determine the current that flows in the ring oscillator in the voltage-controlled oscillator according to the current which is supplied from the current supply and the size ratio between the voltage-to-current conversion transistor and the first transistor.

Further, in order to solve the above-described problems, according to claim 3 of the present invention, in the PLL burn-in circuit defined in claim 1, the voltage switching means includes a switching element which switches the state between the gate terminal and the drain terminal of the first transistor, between the high-impedance state and the connected state.

Therefore, the state between the drain terminal of the voltage-to-current conversion transistor and the gate terminal of the first transistor is put in the high impedance state by using the switching circuit during the normal operation to put the gate terminal of the voltage-to-current conversion transistor in the high impedance state, thereby to disconnect the PLL burn-in circuit from the voltage-controlled oscillator, while the gate terminal and the drain terminal of the first transistor are connected during the burn-in test, thereby to determine the current that flows in the ring oscillator in the voltage-controlled oscillator according to the current which is supplied from the current supply and the size ratio between the voltage-to-current conversion transistor and the first transistor.

Further, in order to solve the above-described problems, according to claim 4 of the present invention, in the PLL burn-in circuit defined in claim 1, the voltage switching means includes a diode connection path diode-connecting the gate terminal and the drain terminal of the first transistor, and a switching element which switches the state between the source terminal of the first transistor and the second power supply, between the high-impedance state and the connected state.

Therefore, the state between the source terminal of the first transistor and the second power supply is put in the high impedance state by using the switching circuit during the normal operation to put the control input terminal in the high impedance state, thereby to disconnect the PLL burn-in circuit from the voltage-controlled oscillator, while the source terminal of the first transistor is connected to the second power supply during the burn-in test, thereby to determine the current that flows in the ring oscillator in the voltage-controlled oscillator according to the current which is supplied from the current supply and the size ratio between the voltage-to-current conversion transistor and the first transistor.

Further, in order to solve the above-described problems, according to claim 5 of the present invention, the PLL burn-in circuit defined in claim 2 includes, instead of the switching element, a series-connected unit which is obtained by connecting a resistor and a switching element in series, between the gate terminal of the voltage-to-current transistor and the gate terminal of the first transistor.

Therefore, since the resistor serves as a protection element for ESD, the resistance of the first transistor to ESD can be increased.

Further, in order to solve the above-described problems, according to claim 6 of the present invention, in the PLL burn-in circuit defined in claim 3 or 4, a resistor is inserted between the gate terminal of the voltage-to-current conversion transistor and the gate terminal of the first transistor.

Therefore, since the resistor serves as a protection element for ESD, the resistance of the first transistor to ESD can be increased.

Further, in order to solve the above-described problems, according to claim 7 of the present invention, in the PLL burn-in circuit defined in claim 1, the current supply comprises a resistor.

Therefore, since the resistor can generate a current proportional to the inter-terminal voltage, a current close to a target value can be supplied to the first transistor.

Further, in order to solve the above-described problems, according to claim 8 of the present invention, in the PLL burn-in circuit defined in claim 1, the current supply comprises a transistor.

Therefore, the current can be controlled with a higher precision relative to the case where the current supply is configured by a resistor, and thereby the precision of the load applied to the circuit during the burn-in test can be increased.

Further, in order to solve the above-described problems, according to claim 9 of the present invention, in the PLL burn-in circuit defined in any of claims 2 to 4, the current supply is a variable current supply whose current amount can be controlled.

Therefore, by controlling the current amount of the current supply, a current which is more suitable for performing the burn-in test can be supplied to the ring oscillator in the voltage-controlled oscillator.

Further, in order to solve the above-described problems, according to claim 10 of the present invention, the PLL burn-in circuit defined in claim 9 further includes a monitor circuit which monitors the frequency of the signal outputted from the voltage-controlled oscillator, and varies the current amount of the variable current supply in accordance with the monitoring result.

Therefore, by controlling the current amount of the current supply using the result obtained by monitoring the output signal from the voltage-controlled oscillator, the current amount can be controlled by the oscillation frequency of the voltage-controlled oscillator during the burn-in test.

Further, in order to solve the above-described problems, according to claim 11 of the present invention, the PLL burn-in circuit defined in any of claims 2 to 4 includes the first transistor having a variable transistor size, and a transistor size varying means which varies the transistor size of the first transistor.

Therefore, by varying the size of the first transistor with the transistor size varying means, the current amount that flows in the ring oscillator in the voltage-controlled oscillator can be controlled to a value that is suitable for performing the burn-in test.

Further, in order to solve the above-described problems, according to claim 12 of the present invention, there is provided a semiconductor integrated circuit comprising: a current supply which generates a current; a conversion circuit which converts the current from the current supply into a current of a predetermined amount by a current mirror; and an oscillation circuit which receives the converted current and is oscillated with a frequency according to the value of the current when performing a test.

Therefore, a current of a stable value can be supplied to the oscillation circuit as an input current for its oscillation frequency control.

### EFFECTS OF THE INVENTION

In the PLL burn-in circuit of the present invention, a current mirror circuit is formed by diode-connecting a transistor of the same polarity as the input transistor of the voltage-controlled oscillator, and thereby the current that flows in the voltage-controlled oscillator is controlled by the current supplied from the current supply and the transistor size. Therefore, the current that flows in the ring oscillator in the voltage-controlled oscillator can be controlled without being practically affected by variations in the voltage-to-current conversion transistor in the voltage-controlled oscillator.

In addition, it is not necessary to modify the voltage-controlled oscillator itself, and area reduction can be achieved by using not the conventional resistor elements of relatively large areas but the transistors, thereby realizing cost reduction.

Accordingly, it is possible to solve the problem in the prior art such as that a failure like non-oscillation of the voltage-controlled oscillator occurs due to that the voltage applied to the voltage-controlled oscillator is adversely affected by element variations or the like and thereby an appropriate burn-in cannot be performed.

Further, in the semiconductor integrated circuit of the present invention, the current supplied from the current source is converted into a current of a predetermined current amount by the current mirror and, when performing the test, the converted current is input to the oscillation circuit to oscillate the oscillation circuit with a frequency according to the value of the current. Therefore, the current that flows in the oscillation circuit can be controlled without being practically affected by variations in the elements in the oscillation circuit.

Accordingly, it is possible to solve the problem in the prior art such as that a failure like non-oscillation of the oscillation circuit occurs due to that the voltage applied to the oscillation circuit is adversely affected by element variations or the like and thereby an appropriate burn-in cannot be performed.

### BRIEF DESCRIPTION OF THE DRAWINGS

FIG. 1 is a circuit diagram illustrating a PLL burn-in circuit according to a first embodiment of the present invention.

FIG. 2 is a circuit diagram illustrating a PLL burn-in circuit according to a second embodiment of the present invention.

FIG. 3 is a circuit diagram illustrating a PLL burn-in circuit according to a third embodiment of the present invention.

FIG. 4 is a circuit diagram illustrating a PLL burn-in circuit according to a fourth embodiment of the present invention.

FIG. 5 is a circuit diagram illustrating a PLL burn-in circuit according to the fourth embodiment of the present invention.

FIG. 6 is a circuit diagram illustrating a PLL burn-in circuit according to the fourth embodiment of the present invention.

FIG. 7 is a circuit diagram illustrating a PLL burn-in circuit according to a fifth embodiment of the present invention.

FIG. 8 is a circuit diagram illustrating a PLL burn-in circuit according to the fifth embodiment of the present invention.

FIG. 9 is a circuit diagram illustrating a PLL burn-in circuit according to the fifth embodiment of the present invention.

FIG. 10 is a circuit diagram illustrating a PLL burn-in circuit according to a sixth embodiment of the present invention.

FIG. 11 is a circuit diagram illustrating a PLL burn-in circuit according to the sixth embodiment of the present invention.

FIG. 12 is a circuit diagram illustrating a PLL burn-in circuit according to the sixth embodiment of the present invention.

FIG. 13 is a circuit diagram illustrating a PLL burn-in circuit according to a seventh embodiment of the present invention.

FIG. 14 is a circuit diagram illustrating a PLL burn-in circuit according to the seventh embodiment of the present invention.

FIG. 15 is a circuit diagram illustrating a PLL burn-in circuit according to the seventh embodiment of the present invention.

FIG. 16 is a diagram illustrating a general configuration of a PLL which adopts the present invention.

FIG. 17 is a diagram illustrating a configuration of a general voltage-controlled oscillator.

FIG. 18 is a diagram illustrating the relation between the loop filter voltage and the oscillation frequency in the voltage-controlled oscillator.

FIG. 19 is a circuit diagram illustrating a conventional example of a PLL burn-in circuit.

FIG. 20 is a circuit diagram illustrating another conventional example of a PLL burn-in circuit.

### DESCRIPTION OF REFERENCE NUMERALS

10 . . . voltage-controlled oscillator
11 . . . voltage-to-current conversion transistor Tr1 in voltage-controlled oscillator
12a,12b,12c . . . switch
13 . . . transistor Tr2 having the same polarity as transistor Tr1
13a . . . diode connection path
14 . . . current supply
14a . . . variable current supply
15,15a . . . resistor
16 . . . monitor circuit
20,21,22,23,24,25,26 . . . PLL burn-in circuit
23a,24a,25a,131,132,133 . . . series-connection unit
60 . . . control circuit
100 . . . semiconductor integrated circuit
101 . . . control input terminal
130 . . . size-variable transistor
200 . . . PLL
300 . . . control terminal voltage setting means

### MEASURES TO SOLVE THE PROBLEMS

### Best Mode to Execute the Invention

Hereinafter, the best mode to execute the present invention will be described.

### Embodiment 1

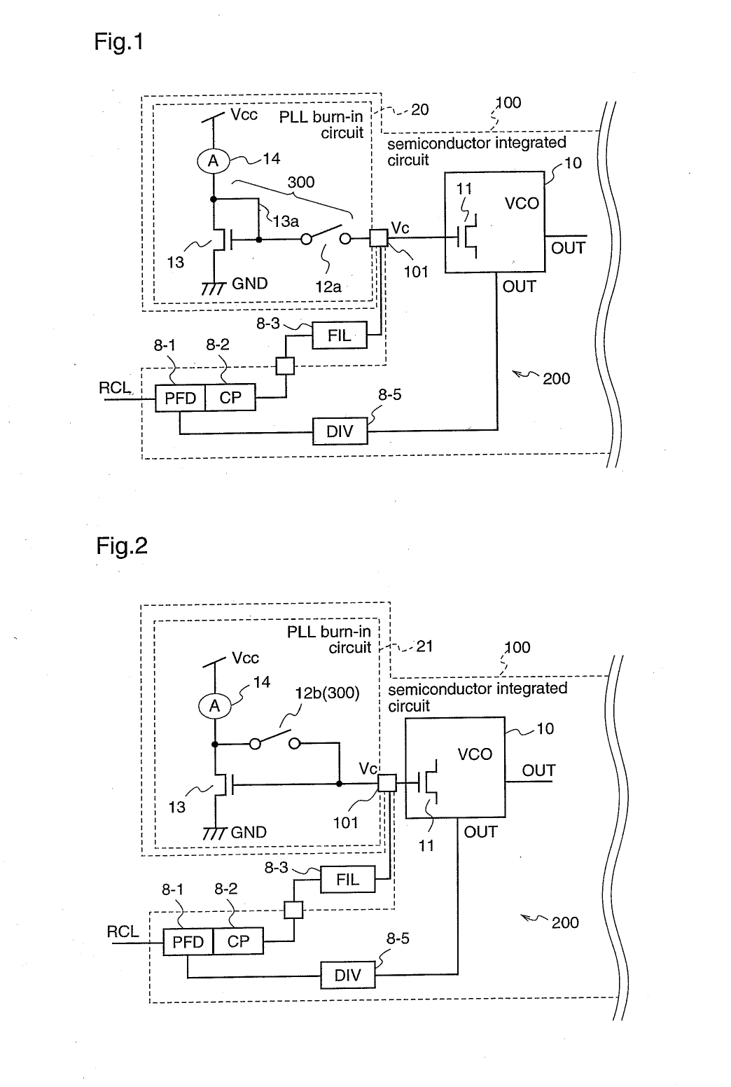

FIG. 1 shows a PLL burn-in circuit according to a first embodiment of the present invention. In FIG. 1, a PLL circuit 200 excluding a loop filter (FIL) 8-3, i.e., a PLL circuit 200 comprising a phase comparator (PFD) 8-1, a charge pump (CP) 8-2, a feedback frequency-divider (DIV) 8-5, and a voltage-controlled oscillator (VCO) 10 is embedded in a semiconductor integrated circuit 100, and further, a PLL burn-in circuit 20 is also embedded therein.

In the semiconductor integrated circuit 100, the PLL burn-in circuit 20 connected to the voltage-controlled oscillator (corresponding to the VCO 8-4 in FIG. 8) comprises a transistor (first transistor) Tr2 13 having the same polarity as a transistor (voltage-to-current conversion transistor) Tr1 11 which converts a control voltage into a current in the voltage-controlled oscillator 10, a diode connection path 13a which diode-connects a drain terminal and a gate terminal of the transistor Tr2 13, a current supply A1 14, and a switch SW1 12a.

More specifically, an end of the current supply A1 14 is connected to a power supply (first power supply) voltage Vcc while the other end thereof is connected to the drain terminal of the transistor Tr2 13, the gate terminal of the transistor Tr2 13 is connected to the drain terminal thereof and to an end of the switch SW1 12a through the diode connection path 13a, the other end of the switch SW1 12a is connected to the gate terminal of the transistor Tr1 11 in the VCO 10 through the input terminal 101, and the source terminal of the transistor Tr2 13 is connected to the ground (second power supply) voltage GND.

Further, a control terminal voltage setting means 300 is configured by the diode connection path 13a and the switch 12a.

Furthermore, all the constituents of the PLL 200, i.e., the VCO 10, the phase comparator 8-1, the charge pump 8-2, and the feedback frequency-divider 8-5, are included in the semiconductor integrated circuit 100 except that the loop filter 8-3 is externally attached to the semiconductor integrated circuit 100 as described above.

Next, the operation will be described. The switch SW1 12a is set in the high impedance state during the normal operation to separate the voltage-controlled oscillator 10 in the PLL 200 from the PLL burn-in circuit 20. On the other hand, the switch SW1 12a is set in the conduction state during the PLL burn-in. When the switch SW1 12a is set in the conduction state, since the gate terminal of the transistor Tr1 11 is at the same voltage as the gate terminal of the diode-connected transistor Tr2 13, a current proportional to the size ratio between the transistor Tr1 11 and the transistor Tr2 13 flows in the transistor Tr1 11. For example, assuming that the current at the current supply A1 14 is 10 μA and the size ratio between the transistor Tr1 11 and the transistor Tr2 13 is 5:2, the current that flows in the transistor Tr1 11 is 10 μA×5÷2=25 μA.

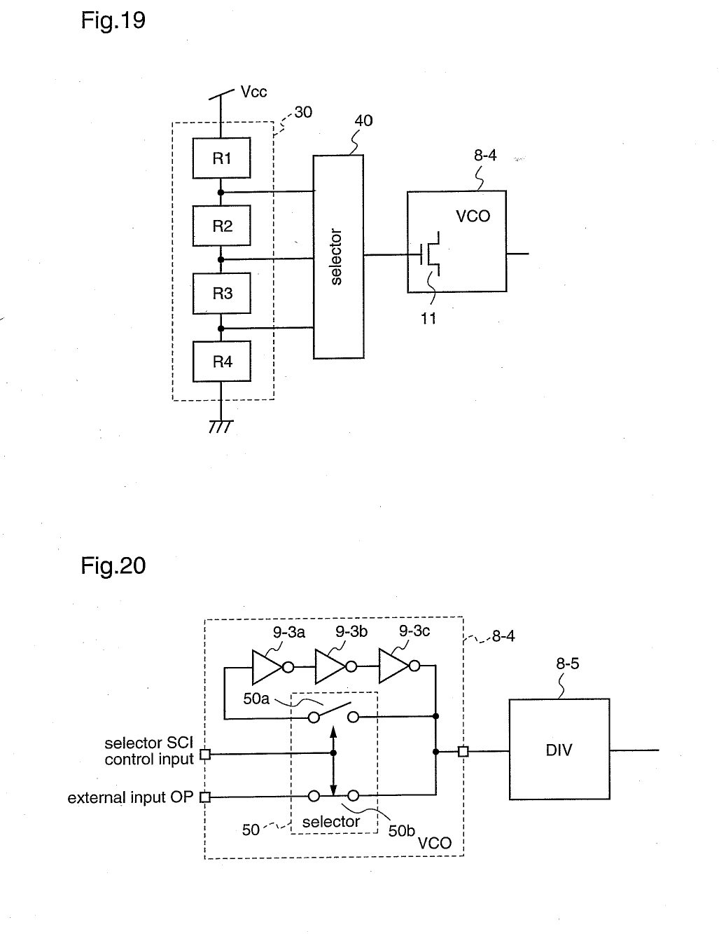

In the case where one of the divided voltages which are generated using such as the voltage-division resistor 30 comprising the plural resistor elements R1 to R4 connected in series is selected by the selector 40 to be applied to the control voltage input terminal of the voltage-controlled oscillator 8-4 to oscillate the voltage-controlled oscillator 8-4 as shown in FIG. 19, the input voltage to the voltage-controlled oscillator is varied due to variations caused by individual differences of the resistor elements R1 to R4, and further, the current that flows in the ring oscillator is varied due to variations caused by individual difference of the transistor Tr1 11, resulting in difficulty to approximate the oscillation frequency of the voltage-controlled oscillator to a desired frequency.

In the configuration of the PLL burn-in circuit of this first embodiment, however, the current that flows in the transistor Tr1 11 can be accurately determined based on the current supplied from the current supply A1 14 and the size ratio between the transistor Tr1 11 and the transistor Tr2 13.

To be specific, when the switch SW1 12a is in the conduction state, the transistor Tr1 11 and the transistor Tr2 13 configure a current mirror circuit, and thereby a current proportional to the current which is supplied from the current source A1 14 to the transistor Tr2 13 can be supplied to the transistor Tr1 11.

Therefore, the current that flows in the transistor Tr1 11 is not varied, and an appropriate current can be supplied to the ring oscillator in the voltage-controlled oscillator without being affected by element variations or the like, and thereby the oscillation frequency of the voltage-controlled oscillator 10 can be stabilized, and a burn-in test with an optimum frequency can be carried out by the simple configuration.

As described above, according to the first embodiment, there is provided the transistor Tr2 13 which configures a current mirror circuit together with the transistor Tr1 11 that receives at its gate the control voltage of the voltage-controlled oscillator 10 during burn-in, and a constant current is supplied from the current supply A1 14 to this transistor Tr2 13 when the switch SW1 12a provided between the gates of the transistors 11 and 13 is closed. Therefore, an appropriate constant current can be supplied to the ring oscillator in the voltage-controlled oscillator without being affected by element variations or the like, and thereby a burn-in test with an optimum frequency can be carried out while minimizing the area of the circuit added for the burn-in test.

### Embodiment 2

FIG. 2 shows a PLL burn-in circuit according to a second embodiment of the present invention. In FIG. 2, a PLL burn-in circuit 21 connected to the voltage-controlled oscillator 10 comprises a transistor Tr2 13 having the same polarity as a transistor Tr1 11 which converts a control voltage into a current in the voltage-controlled oscillator 10, a diode connection path 13a which diode-connects a drain terminal and a gate terminal of the transistor Tr2 13, a current supply A1 14, and a switch SW2 12a which is provided in the diode connection path 13a.

That is, an end of the current supply A1 14 is connected to the power supply voltage Vcc while the other end thereof is connected to the drain terminal of the transistor Tr2 13, the gate terminal of the transistor Tr2 13 is connected to the gate terminal of the transistor Tr1 11 via an input terminal 101 and to an end of the switch SW2 12b which is provided in the diode connection path 13a, the other end of the switch SW2 12b is connected to the drain terminal of the transistor Tr2 13, and the source terminal of the transistor Tr2 13 is connected to the ground voltage GND.

This configuration is identical to the first embodiment except that the switch 12b is provided in the diode connection path 13a of the transistor TR13 instead of the switch 12a which is provided between the gates of the transistor Tr1 11 and the transistor Tr2 13.

Next, the operation will be described. The switch SW2 12b is put in the high impedance state when performing normal operation. On the other hand, the switch SW2 12b is put in the conduction state when performing PLL burn-in. When the switch SW2 12b is in the conduction state, a current proportional to the size ratio between the transistor Tr1 11 and the transistor Tr2 13 flows in the transistor Tr1 11, and thereby the oscillation frequency of the voltage-controlled oscillator 10 can be easily controlled.

That is, when the switch SW2 12b is in the conduction state, the transistor Tr 11 and the transistor Tr2 13 configure a current mirror circuit, and thereby a current proportional to the current which is supplied from the current supply A1 14 to the transistor Tr2 13 can be supplied to the transistor Tr1 11.

Thereby, the current that flows in the transistor Tr1 11 is not varied, and the oscillation frequency of the voltage-controlled oscillator 10 can be stabilized by the simple configuration.

As described above, according to this second embodiment, there are provided the transistor Tr2 13 which configures a current mirror circuit together with the transistor Tr1 11 which receives at its gate the control voltage of the voltage-controlled oscillator 10 during the burn-in, and the switch SW2 12b placed between the gate and the drain of the transistor Tr12, and a constant current is supplied from the current supply A1 to the transistor Tr12 when this switch SW2 12b is closed. Therefore, the current that flows in the transistor Tr1 11 is not varied, and an appropriate constant current can be supplied to the ring oscillator in the voltage-controlled oscillator without being affected by element variations or the like, and thereby a burn-in test with an optimum frequency can be carried out while minimizing the area of the circuit added for the burn-in test.

### Embodiment 3

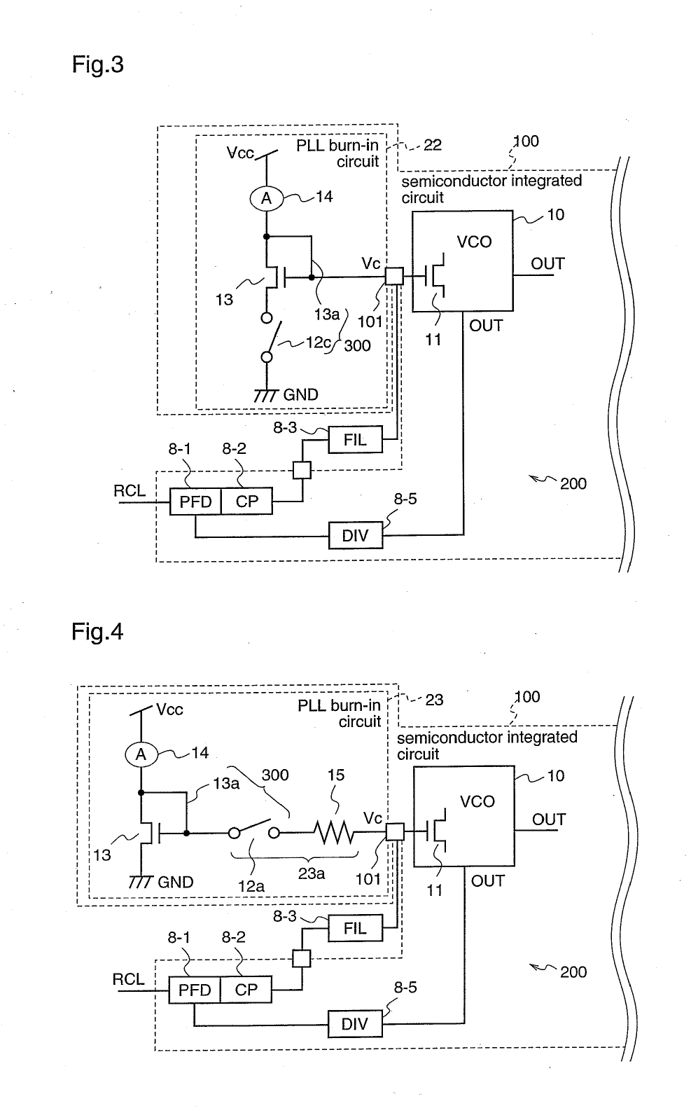

FIG. 3 shows a PLL burn-in circuit according to a third embodiment of the present invention. In FIG. 3, a PLL burn-in circuit 22 connected to the voltage-controlled oscillator 10 comprises a transistor Tr2 13 having the same polarity as a transistor Tr1 11 which converts a control voltage into a current in the voltage-controlled oscillator 10, a diode connection path 13a which diode-connects a drain terminal and a gate terminal of the transistor Tr2 13, a current supply A1 14, and a switch SW3 12c.

More specifically, an end of the current supply A1 14 is connected to the power supply voltage Vcc while the other end thereof is connected to the drain terminal of the transistor Tr2 13, the gate terminal of the transistor Tr2 13 is connected to the drain terminal thereof via the diode connection path 13a and to the gate terminal of the transistor Tr1 11 via an input terminal 101, and an end of the switch Sw3 12c is connected to the source terminal of the transistor Tr2 13 while the other end thereof is connected to the ground voltage.

Next, the operation will be described. The switch SW3 12c is put in the high impedance state when performing normal operation to separate the voltage-controlled oscillator 10 from the PLL burn-in circuit 20. On the other hand, the switch SW3 12c is put in the conduction state when performing PLL burn-in. When the switch SW3 12 is in the conduction state, a current proportional to the size ratio between the transistor Tr1 11 and the transistor Tr2 13 is supplied to the transistor Tr1 11, and thereby the oscillation frequency of the voltage-controlled oscillator 10 can be easily controlled.

To be specific, when the switch SW3 12c is in the conduction state, the transistor Tr1 11 and the transistor Tr2 13 configure a current mirror circuit, and thereby a current proportional to the current that is supplied from the current supply A1 14 to the transistor Tr2 13 can be supplied to the transistor Tr1 11.

Thereby, the current that flows in the transistor Tr1 11 is not varied, and the oscillation frequency of the voltage-controlled oscillator 10 can be stabilized by the simple configuration.

As described above, according to this third embodiment, there are provided the transistor Tr2 13 which configures a current mirror circuit together with the transistor Tr1 11 which receives at its gate the control voltage of the voltage-controlled oscillator 10 during the burn-in, and the switch SW 3 12c placed between the source of the transistor Tr2 13 and the ground voltage, and a constant current is supplied from the current supply A1 14 to the transistor Tr2 13 by closing this switch SW3 12c. Therefore, an appropriate constant current can be supplied to the ring oscillator in the voltage-controlled oscillator without being affected by element variations or the like, and thereby a burn-in test with the optimum frequency can be performed while minimizing the area of the circuit added for the burn-in test.

### Embodiment 4

FIG. 4 shows a PLL burn-in circuit according to a fourth embodiment of the present invention. In FIG. 4, a PLL burn-in circuit 23 connected to the voltage-controlled oscillator 10 comprises a transistor Tr2 13 having the same polarity as a transistor Tr1 11 which converts a control voltage into a current in the voltage-controlled oscillator 10, a diode connection path 13a which diode-connects a drain terminal and a gate terminal of the transistor Tr2 13, a current supply A1 14, a switch SW1 12a, and a resistor 15.

More specifically, an end of the current supply A1 14 is connected to the power supply voltage Vcc while the other end thereof is connected to the drain terminal of the transistor Tr2 13, the gate terminal of the transistor Tr2 13 is connected to the drain terminal thereof via the diode connection path 13a and to an end of the switch SW1 12a, the other end of the switch SW1 12a is connected to the gate terminal of the transistor Tr1 11 via the resistor 15 and the input terminal 101, and the source terminal of the transistor Tr2 13 is connected to the ground voltage GND.

This configuration is identical to the first embodiment except that the resistor 15 which forms a series-connected unit together with the switch SW1 12a is provided between the switch SW1 12a and the gate terminal of the transistor Tr1 11.

Next, the operation will be described. The switch SW1 12a is put in the high impedance state when performing normal operation, while it is put in the conduction state when performing PLL burn-in. When the switch SW1 12a is in the conduction state, a current proportional to the size ratio between the transistor Tr1 11 and the transistor Tr2 13 is supplied to the transistor Tr1 11. Further, since the resistor 15 is provided between the switch SW1 12a and the gate terminal of the transistor Tr1 11, the influence of ESD (electro-static discharge) from the I/O pin of the semiconductor integrated circuit can be reduced, thereby achieving the effects such as an increase in the resistance to ESD and a reduction in the area of the transistor Tr2.

As described above, according to this fourth embodiment, there are provided the transistor Tr2 13 which configures a current mirror circuit together with the transistor Tr1 11 which receives at its gate the control voltage of the voltage-controlled oscillator 10 when performing burn-in, and the switch SW1 12a placed between the gates of the transistor Tr1 11 and the transistor Tr2 13, and a constant current is supplied from the current supply A1 14 to the transistor Tr2 13 which configures the current mirror circuit by closing this switch SW1 12a. Therefore, an appropriate constant current can be supplied to the ring oscillator in the voltage-controlled oscillator without being affected by element variations or the like, and thereby a burn-in test with the optimum frequency can be performed while minimizing the area of the circuit added for the burn-in test.

Further, since the resistor 15 is inserted between the other end of the switch 12a and the input terminal of the voltage-controlled oscillator 10, the influence of ESD from the I/O pin of the semiconductor integrated circuit having the VCO can be reduced.

If such area increase in the semiconductor integrated circuit is not a problem, the resistor may be omitted and a ESD-compliant transistor may be used instead of the transistor Tr1 11.

Further, the connection order between the switch 12a and the resistor 15 may be inverted.

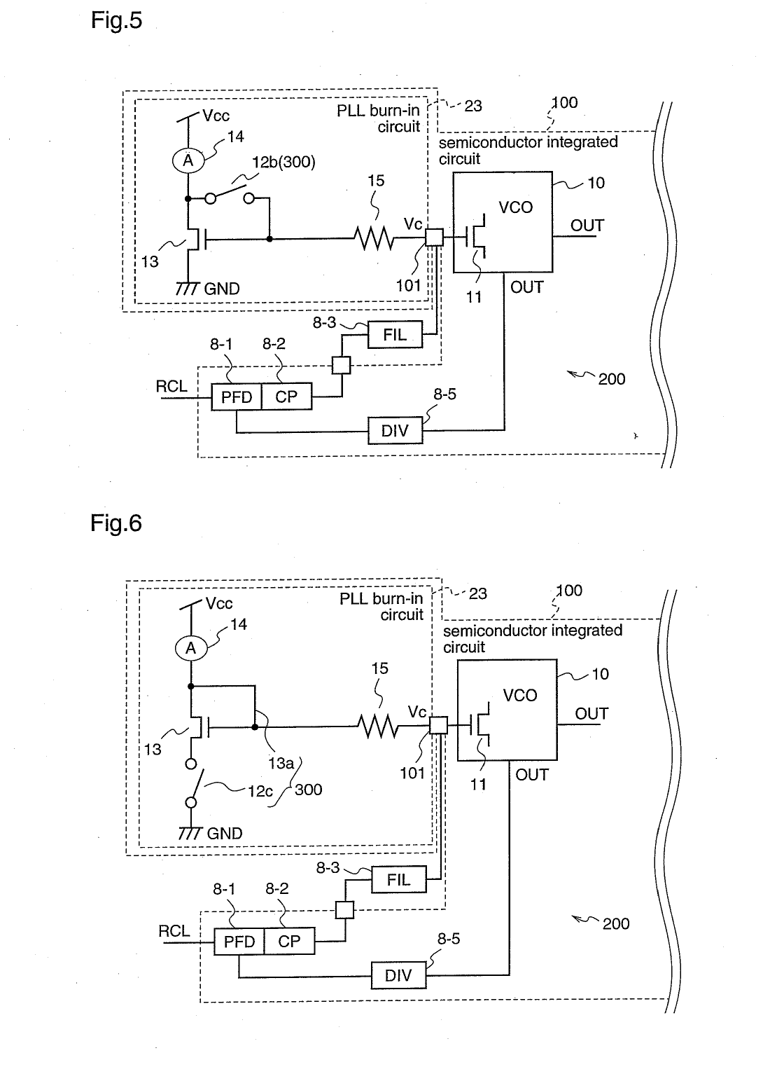

Furthermore, as shown in FIG. 5 or 6, the switch 12b or 12c may be provided in the diode connection path 13a or between the source terminal of the transistor Tr2 13 and the ground voltage GND as in the second or third embodiment, respectively.

### Embodiment 5

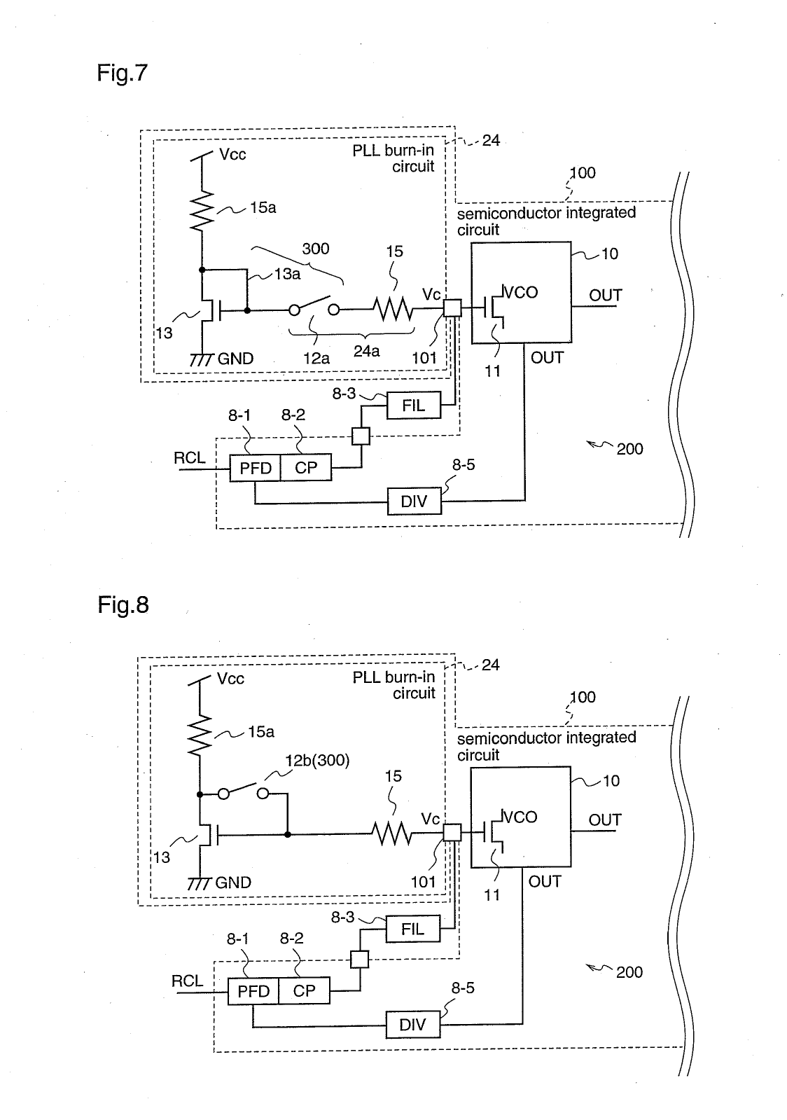

FIG. 7 shows a PLL burn-in circuit according to a fifth embodiment of the present invention. In FIG. 7, a PLL burn-in circuit 24 connected to the voltage-controlled oscillator 10 comprises a transistor Tr2 13 having the same polarity as a transistor Tr1 11 which converts a control voltage into a current in the voltage-controlled oscillator 10, a diode connection path 13a which diode-connects a drain terminal and a gate terminal of the transistor Tr2 13, a resistor RA1 15a, a switch SW1 12a, and a resistor R1 15.

More specifically, an end of the resistor RA1 15a is connected to the power supply voltage Vcc while the other end thereof is connected to the drain terminal of the transistor Tr2 13, the gate terminal of the transistor Tr2 13 is connected to the drain terminal thereof via the diode connection path 13a and to an end of the switch SW1 12a, the other end of the switch SW1 12a is connected to the gate terminal of the transistor Tr1 11 via the resistor R1 15 and the input terminal 101, and the source terminal of the transistor Tr2 13 is connected to the ground voltage.

This configuration is identical to the first embodiment except that the resistor 15 which forms a series-connected unit 24a together with the switch SW1 12a is provided between the switch SW1 12a and the gate terminal of the transistor Tr1 11, and the resistor RA1 15a is provided instead of the current supply A1 14.

Next, the operation will be described. The switch SW1 12a is put in the high impedance state when performing normal operation, while it is put in the conduction state when performing PLL burn-in.

When the switch SW1 12a is in the conduction state, since a current which is determined by the magnitude of the resistance value of the resistor RA1 15a and the voltages applied to the both ends of the resistor RA1 15a is supplied to the transistor Tr2 13, the current that flows in the ring oscillator in the voltage-controlled oscillator 10 can be determined by the magnitude of the resistor RA1 15a and the size ratio between the transistor Tr1 11 and the transistor Tr2 13.

That is, when the switch SW1 12a is in the conduction state, the transistor Tr1 11 and the transistor Tr1 13 configure a current mirror circuit, and thereby a current proportional to the current that is supplied from the current supply A1 14 to the transistor Tr 2 13 can be supplied to the transistor Tr1 11.

Thereby, the current that flows in the transistor Tr1 11 is not varied, and the oscillation frequency of the voltage-controlled oscillator 10 can be stabilized by the simple configuration.

As described above, according to this fifth embodiment, there are provided the transistor Tr2 which configures a current mirror circuit together with the transistor Tr1 which receives at its gate the control voltage of the voltage-controlled oscillator 10 when performing burn-in, and the switch SW1 12a placed between the gates of the transistor Tr1 11 and the transistor Tr2 13, and a constant current is supplied from the resistor RA1 15a to the transistor Tr2 by closing the switch SW1 12a. Therefore, the current that flows in the transistor Tr1 11 is not varied, and an appropriate current can be supplied to the ring oscillator in the voltage-controlled oscillator without being affected by element variations or the like, and thereby a burn-in test with the optimum frequency can be performed while minimizing the area of the circuit added for the burn-in test.

Further, since the resistor 15 is inserted between the other end of the switch 12a and the input terminal of the voltage-controlled oscillator 10, the influence of ESD from the I/O pin of the semiconductor integrated circuit having the VCO can be reduced.

The resistor RA1 15a can also be configured by diode-connecting a transistor whose polarity is different from that of the transistor Tr1.

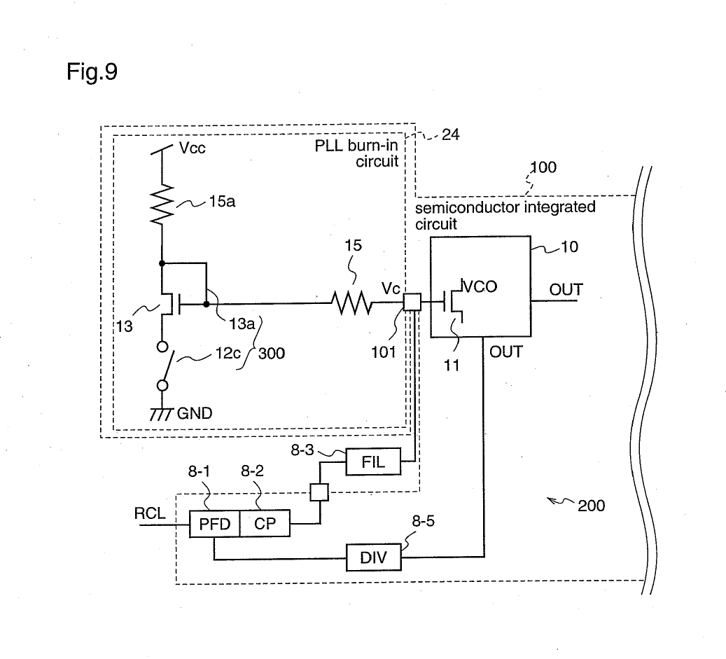

Further, as shown in FIG. 8 or 9, the switch 12b or 12c may be provided in the diode connection path 13a or between the source terminal of the transistor Tr2 13 and the ground voltage GND as in the second or third embodiment, respectively.

Furthermore, also in the first to fourth embodiments, the resistor RA1 15a may be provided instead of the current supply 14 with the same effect of the fifth embodiment.

### Embodiment 6

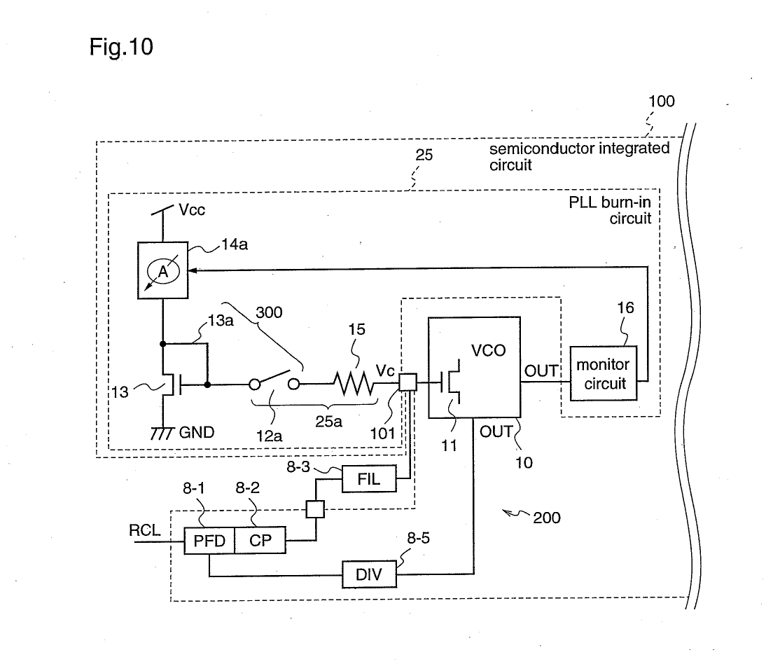

FIG. 10 shows a PLL burn-in circuit according to a sixth embodiment of the present invention. In FIG. 10, a PLL burn-in circuit 25 connected to the voltage-controlled oscillator 10 comprises a transistor Tr2 13 having the same polarity as a transistor Tr1 11 which converts a control voltage into a current in the voltage-controlled oscillator 10, a diode connection path 13a which diode-connects a drain terminal and a gate terminal of the transistor Tr2 13, a variable current supply A2 14a, a switch SW1 12a, a resistor R1 15, and a monitor circuit 16 which monitors the output signal from the voltage-controlled oscillator 10 and outputs the result according to the oscillation frequency as a digital signal.

More specifically, an end of the variable current supply A2 14a is connected to the power supply voltage Vcc while the other end thereof is connected to the drain terminal of the transistor Tr2 13, the gate terminal of the transistor Tr2 13 is connected to the drain terminal thereof via the diode connection path 13a and to an end of the switch SW1 12a, the other end of the switch SW1 12a is connected through the resistor R1 15 and the input terminal 101 to the gate terminal of the transistor Tr1 11 which converts a control voltage into a current in the voltage-controlled oscillator 10, the source terminal of the transistor Tr2 13 is connected to the ground voltage, and the monitor circuit 16 controls the magnitude of the current that is supplied from the variable current supply A2 14a in accordance with the result obtained by monitoring the oscillation frequency of the signal outputted from the voltage-controlled oscillator 10.

Next, the operation will be described. The switch SW1 12a is put in the high impedance state when performing normal operation while it is put in the conduction state when performing PLL burn-in, and thereby the operation is switched. When the switch SW1 12a is in the conduction state, since a current which is determined by the variable current supply A2 14a is supplied to the transistor Tr2 13, a current which is determined by the current supplied from the variable current supply A2 14a and the size ratio between the transistor Tr1 11 and the transistor Tr2 13 is supplied to the ring oscillator in the voltage-controlled oscillator 10.

The monitor circuit 16 monitors the oscillation frequency of the output signal OUT from the voltage-controlled oscillator 10, and controls the current supplied from the variable current supply A2 14a in accordance with the monitored result, and thereby the output signal frequency of the voltage-controlled oscillator during the burn-in test can be set to an appropriate value.

As described above, according to this sixth embodiment, there are provided the transistor Tr2 which configures a current mirror circuit together with the transistor Tr1 which receives at its gate the control voltage of the voltage-controlled oscillator 10 when performing burn-in, and the switch SW1 12a placed between the gates of the transistor Tr1 11 and the transistor Tr2 13, and a constant current whose current value is variable is supplied from the variable current source A2 14a to this transistor Tr2 by closing the switch SW1 12a. Therefore, the current that flows in the transistor Tr1 11 is not varied, and an appropriate current can be supplied to the ring oscillator in the voltage-controlled oscillator without being affected by element variations or the like, and thereby a burn-in test with the optimum frequency can be performed while minimizing the area of the circuit added for the burn-in test.

Further, since the resistor 15 is inserted between the other end of the switch 12a and the input terminal of the VCO 10, the influence of ESD from the I/O pin of the semiconductor integrated circuit having the VCO can be reduced.

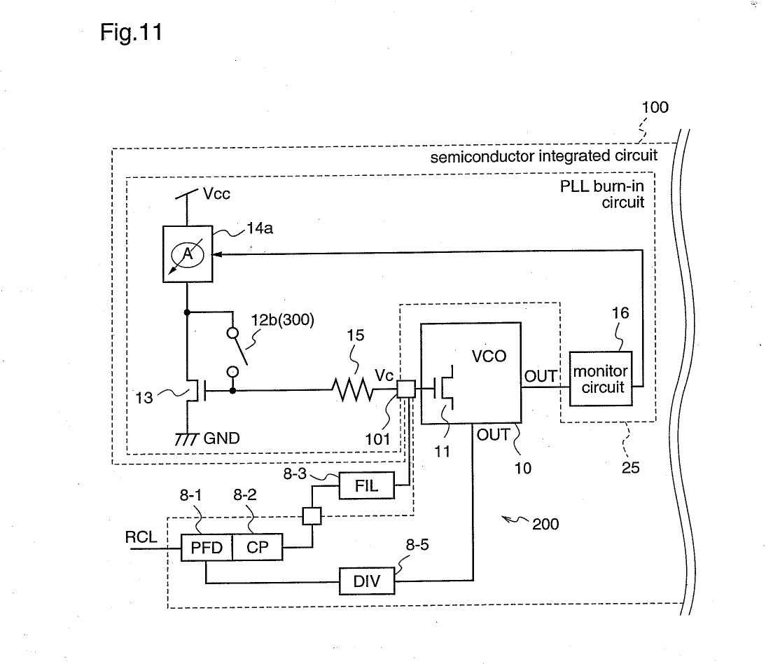

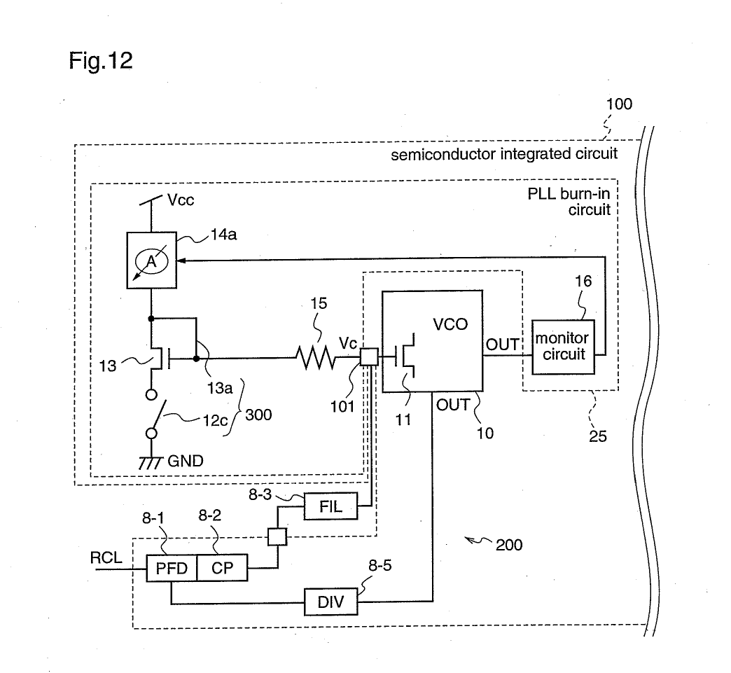

Further, as shown in FIG. 11 or 12, the switch 12b or 12c may be provided in the diode connection path 13a or between the source terminal of the transistor Tr2 13 and the ground voltage GND as in the second or third embodiment, respectively.

Furthermore, also in the first to fourth embodiments, the variable current supply 14a and the monitor circuit 16 may be provided instead of the current supply 14 with the same effect of the sixth embodiment.

### Embodiment 7

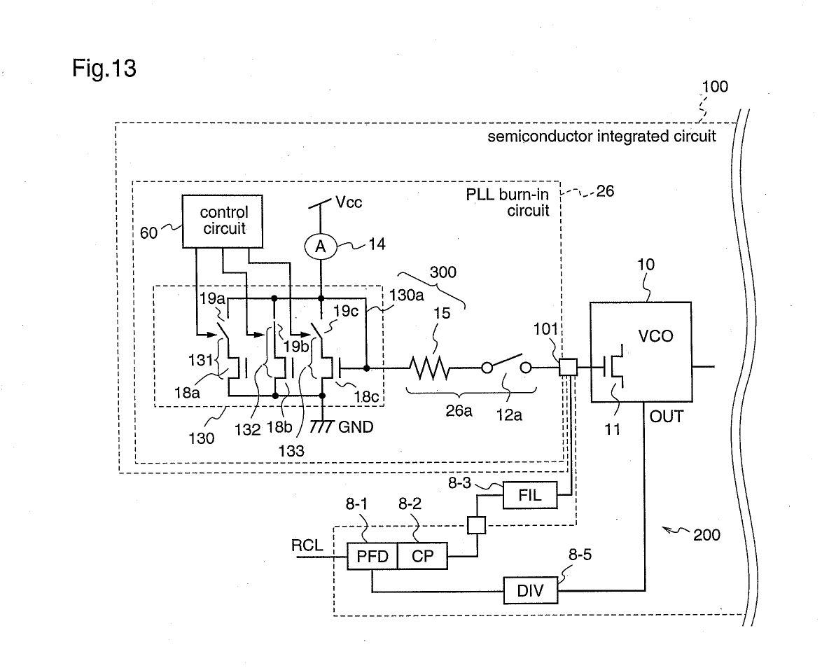

FIG. 13 shows a PLL burn-in circuit according to a seventh embodiment of the present invention. In FIG. 13, a PLL burn-in circuit 26 connected to the voltage-controlled oscillator 10 comprises a transistor Tr2 130 which has the same polarity as a transistor Tr1 11 that converts a voltage of the voltage-controlled oscillator 10 into a current and has a transistor size which can be varied according to an input from a control input terminal, a diode connection path 13a which diode-connects a drain terminal and a gate terminal of the transistor Tr2 130, a current supply A1 14, a switch SW1 12a, a resistor R1 15, and a control circuit (transistor size variable means) 60 which performs a control to vary the size of the transistor Tr2 130.

More specifically, an end of the current supply A1 14 is connected to the power supply voltage Vcc while the other end thereof is connected to the drain terminal of the transistor Tr2 130, the gate terminal of the transistor Tr2 130 is connected to the drain terminal thereof via the diode connection path 13a and to an end of the resistor R1 15, the other end of the resistor R1 15 is connected to the gate terminal of the transistor Tr1 11 via the switch SW1 12a and the input terminal 101, and the source terminal of the transistor Tr2 130 is connected to the ground voltage.

Further, in FIG. 13, the transistor Tr2 130 comprises three series-connected units 131, 132, and 133. The series-connected unit 131 comprises a transistor 18a and a switch 19a, the series-connected unit 132 comprises a transistor 18b and a switch 19b, and the series-connected unit 133 comprises a transistor 18c and a switch 19c. The drain terminals of the transistors 18a, 18b, and 18c are commonly connected to be the drain terminal of the transistor Tr2 130. One ends of the switches 19a, 19b, and 19c are connected to the source terminals of the transistors 18a, 18b, and 18c, respectively, and the other ends thereof are commonly connected to be the source terminal of the transistor Tr2 130.

Next, the operation will be described. The switch SW1 12a is put in the high impedance state when performing normal operation while it is put in the conduction state when performing PLL burn-in. When the switch SW1 12a is in the conduction state, a current proportional to the size ratio between the transistor Tr1 11 and the transistor Tr2 130 is supplied to the ring oscillator in the voltage-controlled oscillator 10. Since the size of the transistor Tr2 130 can be varied according to the input signal from the control circuit 30, the current that flows into the ring oscillator in the voltage-controlled oscillator 10 can be adjusted as desired by adjusting the two parameters, i.e., the amount of current supplied by the current supply A1 14 and the size of the transistor Tr2 130, and thereby the oscillation frequency of the output signal from the voltage-controlled oscillator can be adjusted to an appropriate value.

As described above, according to the seventh embodiment, there are provided the transistor Tr2 130 which configures a current mirror circuit together with the transistor Tr1 which receives at its gate the control voltage of the voltage-controlled oscillator 10 when performing burn-in, and the switch SW1 12a placed between the transistor Tr1 11 and the transistor Tr2 130, and a constant current is supplied from the current source A1 14 to the transistor Tr2 130 by closing the switch SW1 12a. Therefore, the current that flows in the transistor Tr1 11 is not varied, and an appropriate current can be supplied to the ring oscillator in the voltage-controlled oscillator without being affected by element variations or the like, and thereby a burn-in test with the optimum frequency can be performed while minimizing the area of the circuit added for the burn-in test, and furthermore, the output signal frequency of the voltage-controlled oscillator during the burn-in test can be set to an appropriate value.

Further, since the size of the transistor Tr2 130 can be varied according to the control signal of the control circuit 60, the current that flows in the ring oscillator in the voltage-controlled oscillator can be adjusted as desired by varying the size of the transistor Tr2 130 with the current value of the current source A1 14 being varied, and thereby the oscillation frequency of the output signal from the voltage-controlled oscillator can be adjusted to an appropriate value.

Further, since the resistor 15 is inserted between the switch 12a and the input terminal of the VCO 10, the influence of ESD from the I/O pin of the semiconductor integrated circuit having the VCO can be reduced.

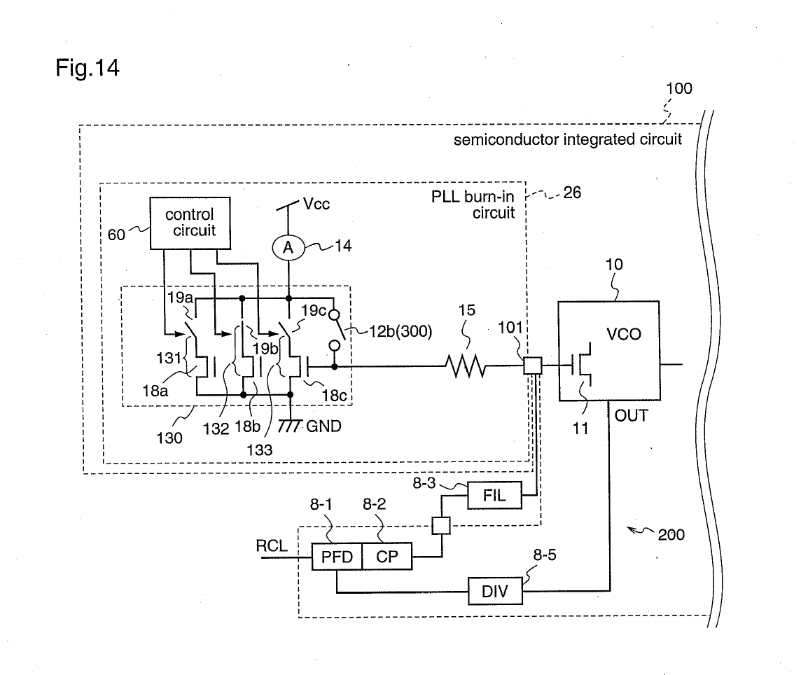

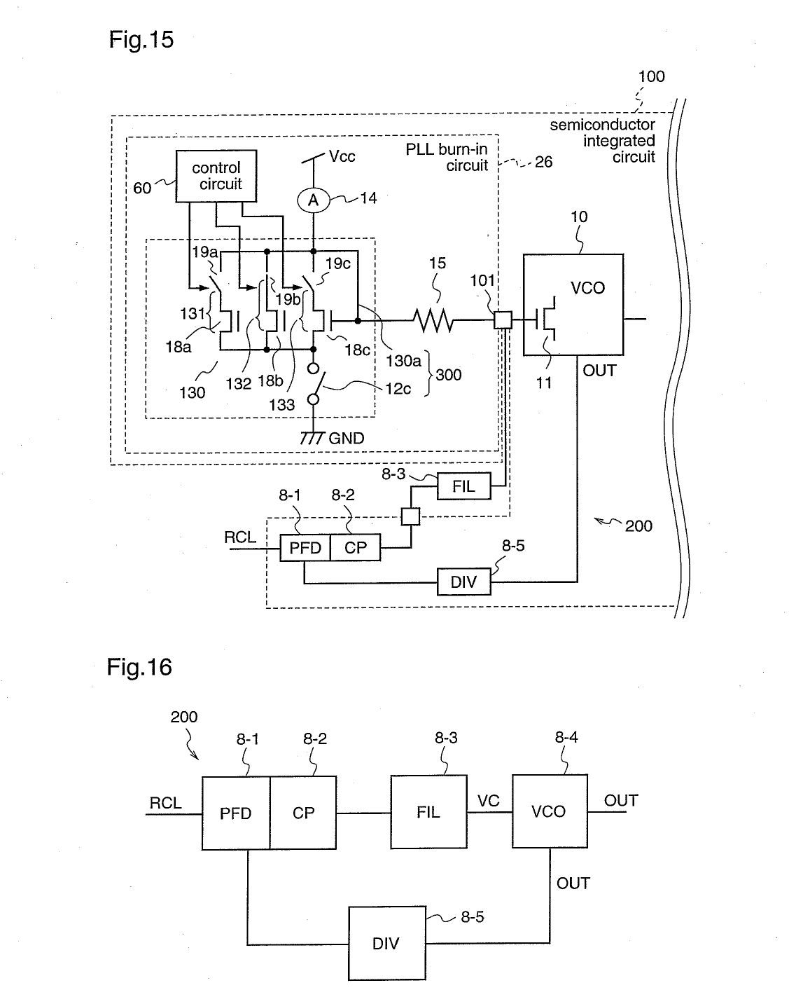

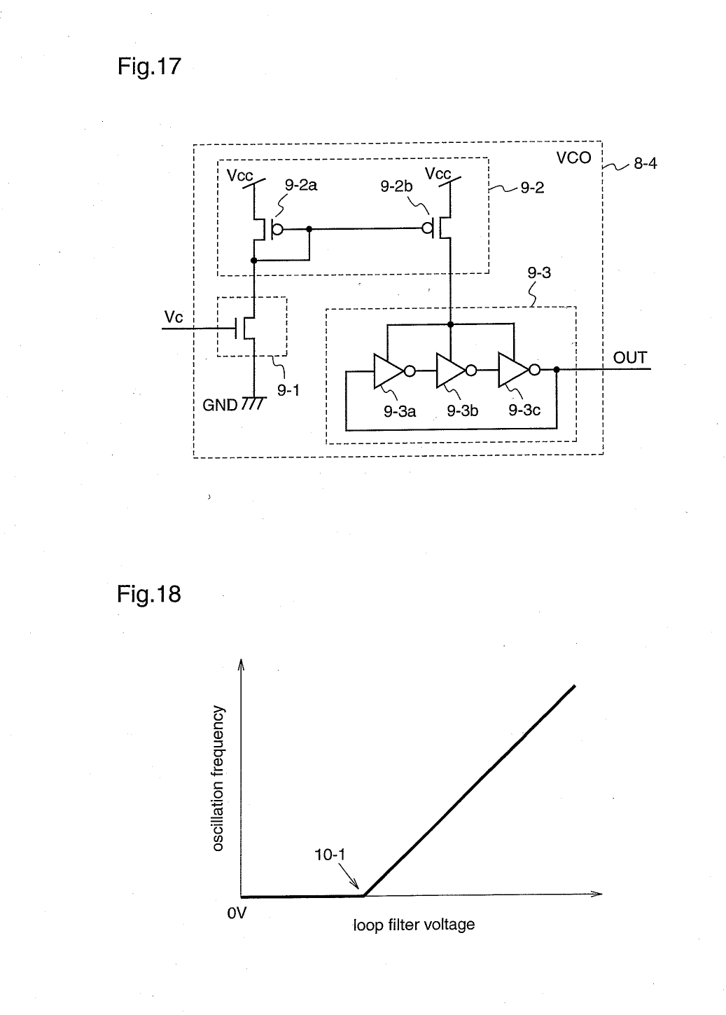

Further, as shown in FIG. 14 or 15, the switch 12b or 12c may be provided in the diode connection path 13a or between the source terminal of the transistor Tr2 130 and the ground voltage GND as in the second or third embodiment, respectively, with the same effect as obtained in the seventh embodiment.

Furthermore, also in the first to fourth embodiments, the transistor 130 and the control circuit 60 may be provided instead of the transistor 13 with the same effect of this seventh embodiment.

While in the second to seventh embodiment the descriptions and illustrations of the semiconductor integrated circuit, the VCO, and the external loop filter are omitted, it is needless to say that the second to seventh embodiments also include these elements identical to those of the first embodiment.

Further, while in the first to seventh embodiments the target of the burn-in test is the PLL circuit, the circuit to be the target may be other than the PLL circuit so long as it has a VCO which does not perform self-propelled oscillation.

Furthermore, while the PLL burn-in circuit according to any of the first to seventh embodiments has the transistor Tr1 11 which is an NMOS transistor, the present invention is also applicable to the case where the transistor 11 is a PMOS transistor. In this case, a PLL burn-in circuit can be configured by interchanging the power supply voltage and the ground voltage.

### APPLICABILITY IN INDUSTRY

As described above, in the PLL burn-in circuit adopting the present invention, the current to be supplied to the ring oscillator in the voltage-controlled oscillator can be adjusted to the current amount suitable to perform a burn-in test without being affected by element variations, and thereby the burn-in test for the voltage-controlled oscillator can be performed with the optimum condition to enhance the reliability of the test. Further, the increase in the area required to apply the present invention is smaller than that of the conventional method, resulting in a cost reduction of the semiconductor integrated circuit.

1. A PLL burn-in circuit which applies a burn-in voltage to a voltage-to-current conversion transistor for converting a voltage applied to its gate terminal into a current, said transistor being included in a voltage-controlled oscillator which constitutes a phase locked loop circuit (hereinafter referred to as a PLL) embedded in a semiconductor integrated circuit, said PLL burn-in circuit comprising:
a current supply having one end connected to a first power supply;
a first transistor which has the same polarity as the voltage-to-current conversion transistor, and has a drain terminal connected to the other end of the current supply and a source terminal connected to a second power supply; and
a voltage switching means which makes the voltage at the gate terminal of the voltage-controlled oscillator equal to the voltages at the gate terminal and the drain (or source) terminal of the first transistor when performing PLL burn-in, and makes the gate terminal of the voltage-to-current conversion transistor have a high impedance when performing normal operation.

2. A PLL burn-in circuit as defined in claim 1 wherein
said voltage switching means includes
a diode connection path diode-connecting the gate terminal and the drain terminal of the first transistor, and
a switching element which switches the state between the gate terminal of the voltage-to-current conversion transistor and the gate terminal of the first transistor, between the high-impedance state and the connected state.

3. A PLL burn-in circuit as defined in claim 1 wherein
said voltage switching means includes a switching element which switches the state between the gate terminal and the drain terminal of the first transistor, between the high-impedance state and the connected state.

4. A PLL burn-in circuit as defined in claim 1 wherein
said voltage switching means includes
a diode connection path diode-connecting the gate terminal and the drain terminal of the first transistor, and
a switching element which switches the state between the source terminal of the first transistor and the second power supply, between the high-impedance state and the connected state.

5. A PLL burn-in circuit as defined in claim 2 including,
instead of the switching element,
a series-connected unit which is obtained by connecting a resistor and a switching element in series, between the gate terminal of the voltage-to-current transistor and the gate terminal of the first transistor.

6. A PLL burn-in circuit as defined in claim 3 wherein
a resistor is inserted between the gate terminal of the voltage-to-current conversion transistor and the gate terminal of the first transistor.

7. A PLL burn-in circuit as defined in claim 1 wherein
said current supply comprises a resistor.

8. A PLL burn-in circuit as defined in claim 1 wherein
said current supply comprises a transistor.

9. A PLL burn-in circuit as defined in claim 2 wherein
said current supply is a variable current supply whose current amount can be controlled.

10. A PLL burn-in circuit as defined in claim 9 further including
a monitor circuit which monitors the frequency of the signal outputted from the voltage-controlled oscillator, and varies the current amount of the variable current supply in accordance with the monitoring result.

11. A PLL burn-in circuit as defined in claim 2 including
said first transistor having a variable transistor size, and
a transistor size varying means which varies the transistor size of the first transistor.

12. A semiconductor integrated circuit comprising:
a current supply which generates a current;
a conversion circuit which converts the current from the current supply into a current of a predetermined amount by a current mirror; and
an oscillation circuit which receives the converted current and is oscillated with a frequency according to the value of the current when performing a test.

13. A PLL burn-in circuit as defined in claim 4 wherein
a resistor is inserted between the gate terminal of the voltage-to-current conversion transistor and the gate terminal of the first transistor.

14. A PLL burn-in circuit as defined in claim 3 wherein
said current supply is a variable current supply whose current amount can be controlled.

15. A PLL burn-in circuit as defined in claim 4 wherein
said current supply is a variable current supply whose current amount can be controlled.

16. A PLL burn-in circuit as defined in claim 14 further including
a monitor circuit which monitors the frequency of the signal outputted from the voltage-controlled oscillator, and varies the current amount of the variable current supply in accordance with the monitoring result.

17. A PLL burn-in circuit as defined in claim 15 further including
a monitor circuit which monitors the frequency of the signal outputted from the voltage-controlled oscillator, and varies the current amount of the variable current supply in accordance with the monitoring result.

18. A PLL burn-in circuit as defined in claim 3 including
said first transistor having a variable transistor size, and
a transistor size varying means which varies the transistor size of the first transistor.

19. A PLL burn-in circuit as defined in claim 4 including
said first transistor having a variable transistor size, and
a transistor size varying means which varies the transistor size of the first transistor.
